(19) United States
(12) Patent Application Publication
(10) Pub. No.: US 2026/0107672 A1
(43) Pub. Date: Apr. 16, 2026

(54) LASER IRRADIATION SYSTEM, LASER IRRADIATION METHOD, AND METHOD FOR MANUFACTURING ORGANIC EL DISPLAY

(71) Applicant: JSW Aktina System Co., Ltd., Yokohama-shi, Kanagawa (JP)

(72) Inventors: Teruaki SHIMOJI, Yokohama-shi, Kanagawa (JP); Rei MATSUSHITA, Yokohama-shi, Kanagawa (JP); Daisuke ITO, Yokohama-shi, Kanagawa (JP); Tamotsu ODAJIMA, Yokohama-shi, Kanagawa (JP)

(73) Assignee: JSW Aktina System Co., Ltd., Yokohama-shi, Kanagawa (JP)

(21) Appl. No.: 19/117,263

(22) PCT Filed: Jul. 12, 2023
(86) PCT No.: PCT/JP2023/025734

§ 371 Date: Mar. 31, 2025

(30) Foreign Application Priority Data
Oct. 20, 2022 (JP) 2022-168424

(51) Int. Cl. H10K 71/20; H10K 59/12; H10P 34/42

(52) U.S. Cl. CPC H10K 71/221; H10K 59/1201; H10P 34/42

(57) ABSTRACT

A laser irradiation system (1) includes: a conveyance stage (150); an observation apparatus (110) that captures an image of a workpiece; a laser irradiation unit (170) that irradiates the workpiece, which is inspected by the observation apparatus, with a laser light; a dust collecting mechanism (130) that sucks gas in a periphery of an irradiation region of the laser light; a processing unit (20) that determines whether or not the workpiece is defective based on a captured image of the workpiece captured before the workpiece is irradiated with the laser light; and a control unit that controls the conveyance stage so that the workpiece is not conveyed toward the laser irradiation unit when it is determined that the workpiece is defective.

### TECHNICAL FIELD

The present invention relates to a laser irradiation system, a laser irradiation method, and a method for manufacturing an organic EL display.

### BACKGROUND ART

Patent Literature 1 discloses a laser lift-off apparatus. In this laser lift-off apparatus, a substrate is irradiated with a linear laser light. Further, the substrate is irradiated with the laser light while the substrate is being conveyed. Furthermore, the laser lift-off apparatus includes a dust collecting unit that collects dust.

### CITATION LIST

### Patent Literature

Patent Literature 1: Japanese Unexamined Patent Application Publication No. 2018-24014

### SUMMARY OF INVENTION

In the above laser lift-off apparatus, when a foreign matter adheres to a substrate, the laser light is absorbed by the foreign matter. Therefore, a failure of separation may occur.

Other challenges and novel features will become apparent from the description herein and the accompanying drawings.

According to an embodiment, a laser irradiation system includes: a conveyance stage configured to convey a workpiece including a separating layer to be separated by laser lift off; an observation apparatus configured to capture an image of the workpiece by detecting light from the workpiece being conveyed; a laser irradiation unit configured to irradiate the workpiece, which is inspected by the observation apparatus, with a laser light along a line direction inclined from a conveying direction in a top view; a dust collecting mechanism configured to suck gas in a periphery of an irradiation region of the laser light; a processing unit configured to determine whether or not the workpiece is defective based on a captured image of the workpiece captured before the workpiece is irradiated with the laser light; and a control unit configured to control, when it is determined that the workpiece is defective, the conveyance stage so that the workpiece is not conveyed toward the laser irradiation unit, and control, when it is determined that the workpiece is non-defective, the conveyance stage so that the workpiece that has been irradiated with the laser light is conveyed toward the observation apparatus in order for the observation apparatus to inspect the workpiece.

According to an embodiment, a laser irradiation method includes the steps of: (a) capturing an image of a workpiece by causing a conveyance stage to convey the workpiece so that the workpiece including a separating layer to be separated by laser lift off passes through an observation apparatus; (b) determining whether or not the workpiece is defective based on the captured image of the workpiece; (c) controlling, when it is determined that the workpiece is defective, the conveyance stage so that the workpiece is not conveyed toward a laser irradiation unit; (d) controlling, when it is determined that the workpiece is non-defective, the conveyance stage so that the workpiece is conveyed toward the laser irradiation unit; (e) causing the laser irradiation unit to irradiate the workpiece with a laser light along a line direction inclined from a conveying direction in a top view; (f) sucking gas in a vicinity of an irradiation region of the laser light; (g) capturing an image of the workpiece by causing the conveyance stage to convey the workpiece so that the workpiece that has been irradiated with the laser light passes through the observation apparatus; and (h) determining whether or not the workpiece is defective based on the captured image of the workpiece that has been irradiated with the laser light.

According to an embodiment, a method for manufacturing an organic EL display includes the processes of: (SA) forming a separating layer over a substrate; (B) forming an element over the separating layer; (SC) separating the substrate from the separating layer; and (SD) laminating a film over the separating layer, in which the process (SC) of separating the substrate from the separating layer comprises the steps of: (C1) capturing an image of a substrate by causing a conveyance stage to convey the substrate so that the substrate passes through an observation apparatus; (C2) determining whether or not the substrate is defective based on the captured image of the substrate; (C3) controlling, when it is determined that the substrate is defective, the conveyance stage so that the substrate is not conveyed toward a laser irradiation unit; (C4) controlling, when it is determined that the substrate is non-defective, the conveyance stage so that the substrate is conveyed toward the laser irradiation unit; (C5) causing the laser irradiation unit to irradiate the substrate with a laser light along a line direction inclined from a conveying direction in a top view; (C6) sucking gas in a vicinity of an irradiation region of the laser light; (C7) capturing an image of the substrate by causing the conveyance stage to convey the substrate so that the substrate that has been irradiated with the laser light passes through the observation apparatus; and (C8) determining whether or not the substrate is defective based on the captured image of the substrate that has been irradiated with the laser light.

According to the embodiment, the productivity of a laser lift-off process can be improved.

### BRIEF DESCRIPTION OF DRAWINGS

FIG. 1 is a block diagram showing an overall configuration of a laser irradiation system according to an embodiment;

FIG. 2 is a top view schematically showing a configuration of an LLO apparatus according to an embodiment;

FIG. 3 is a side view schematically showing a configuration of an LLO apparatus according to an embodiment;

FIG. 4 is a sectional side view schematically showing a configuration of a dust collecting mechanism;

FIG. 5 is a flowchart showing processing for determining whether or not a workpiece is defective performed by a processing apparatus;

FIG. 6 is a cross-sectional view schematically showing an organic EL display apparatus manufactured in a process for manufacturing a laser irradiation system; and

FIG. 7 is a cross-sectional view for explaining a process for manufacturing an organic EL display apparatus.

### DESCRIPTION OF EMBODIMENTS

A laser irradiation system according to this embodiment includes, for example, a laser lift-off apparatus such as a Laser Lift Off (LLO) apparatus. A laser irradiation system irradiates a workpiece including a layer to be separated (hereinafter referred to as a separating layer) with a laser light, thereby performing a laser lift-off process on the workpiece. That is, a substrate to be processed (hereinafter referred to as a processing substrate) can be separated from the separating layer by laser irradiation. The laser irradiation system, a method, and a manufacturing method according to this embodiment will be described below with reference to the drawings.

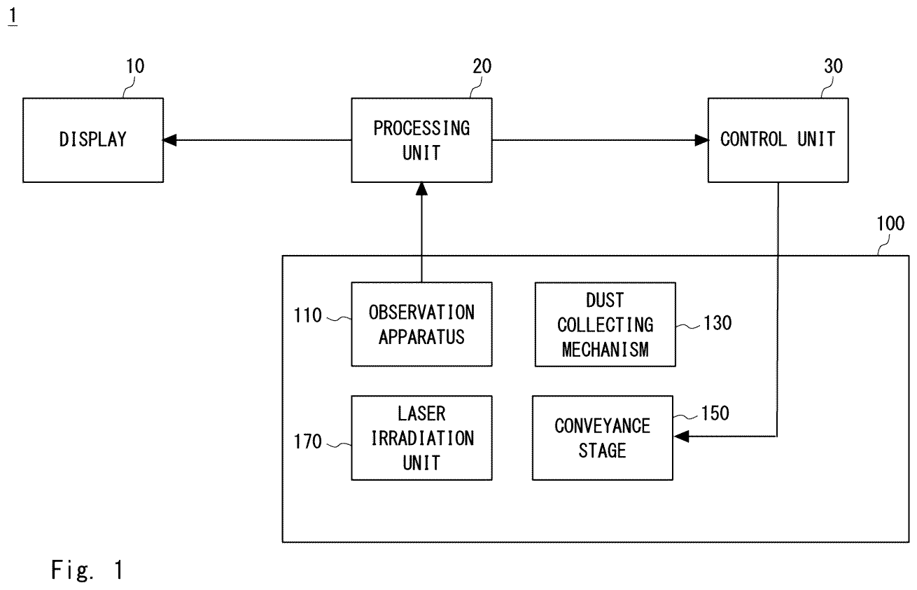

FIG. 1 is a block diagram showing a configuration of a system including an LLO apparatus. A laser irradiation system 1 (hereinafter also referred to simply as a system) includes a display 10, a processing unit 20, a control unit 30, and an LLO apparatus 100. The LLO apparatus 100 includes an observation apparatus 110, a dust collecting mechanism 130, a conveyance stage 150, a laser irradiation unit 170, and the like. A workpiece is a substrate including a separating layer, and elements such as a TFT and an organic light-emitting layer are formed over the separating layer.

The conveyance stage 150 conveys the workpiece. The laser irradiation unit 170 irradiates the workpiece being conveyed with a laser light. The observation apparatus 110 captures an image of the workpiece both before it is irradiated with the laser light and after it is irradiated with the laser light. The processing unit 20 inspects the workpiece based on the captured image of the workpiece. For example, the processing unit 20 detects a foreign matter adhering to the workpiece and determines whether or not the workpiece is defective based on a result of the detection.

The dust collecting mechanism 130 removes a foreign matter from a workpiece W. For example, the dust collecting mechanism 130 sucks gas in the periphery of an irradiation region of the laser light. The dust collecting mechanism 130 can suck a foreign matter present over the workpiece together with gas.

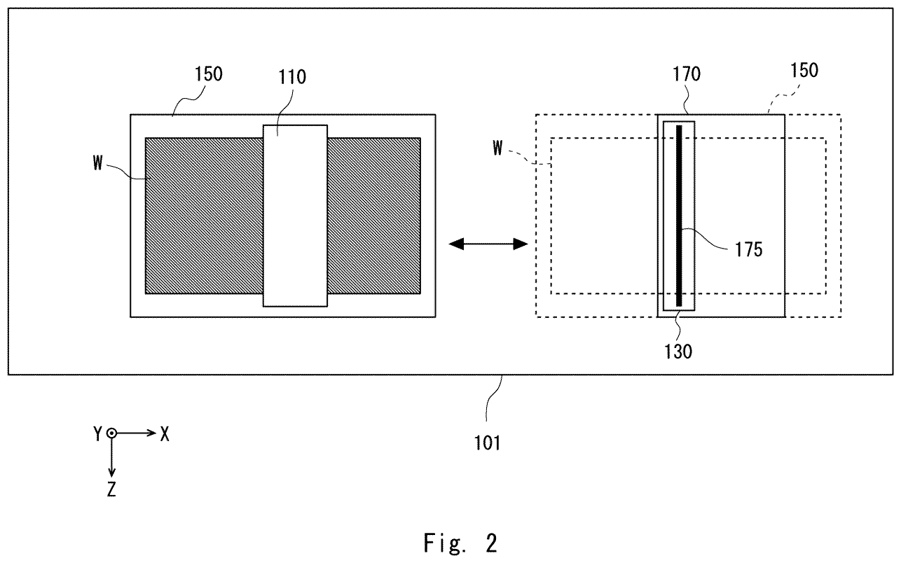

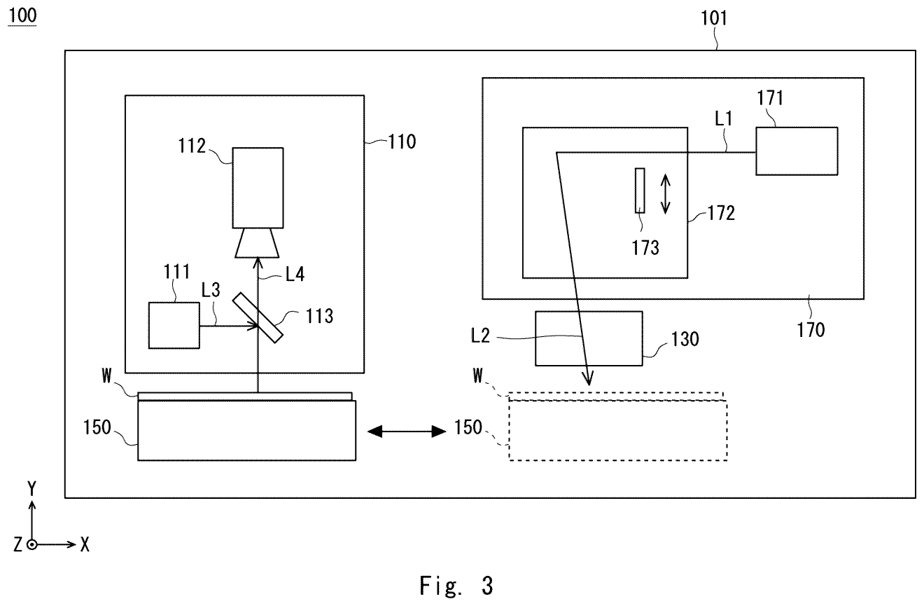

A configuration of each of the conveyance stage 150, the laser irradiation unit 170, the observation apparatus 110, and the dust collecting mechanism 130 will be described with reference to FIGS. 2 and 3. FIG. 2 is a top view schematically showing a configuration of a main part of the LLO apparatus 100, and FIG. 3 is a side view thereof. Note that, in FIGS. 2 and 3, a description will be given as appropriate using an XYZ orthogonal coordinate system. The Y direction is the vertical up/down direction, and the X direction is a conveying direction of the workpiece W.

The laser irradiation unit 170, the conveyance stage 150, the observation apparatus 110, and the dust collecting mechanism 130 are disposed in a chamber 101. The laser irradiation unit 170, the observation apparatus 110, and the dust collecting mechanism 130 are disposed on the upper side of the workpiece W.

The workpiece W is disposed over the conveyance stage 150. The conveyance stage 150 adsorbs and holds the workpiece W. The conveyance stage 150 has, for example, a surface which comes into contact with the workpiece W formed of a porous material such as ceramic. The porous body sucks gas, whereby the workpiece W is adsorbed and held. Further, the conveyance stage 150 includes a guide mechanism (not shown) and a driving motor (not shown). By the above configuration, the workpiece W is moved in the X direction by the operation of the driving motor.

The conveyance stage 150 moves the workpiece W in the X direction while maintaining the workpiece W at a fixed height. The conveyance stage 150 conveys the workpiece W so that it passes through the observation apparatus 110, whereby the observation apparatus 110 captures an image of the workpiece W.

The conveyance stage 150 conveys the workpiece W so that it passes through the laser irradiation unit 170, whereby the laser irradiation unit 170 irradiates the workpiece W with a laser light.

As shown in FIG. 3, the laser irradiation unit 170 includes a laser light source 171 and an irradiation optical system 172. The laser light source 171 includes a laser oscillator that generates a laser light L1. The laser light source 171 is a pulsed laser light source. An excimer laser having a wavelength of 308 nm, a solid-state laser having a wavelength of 343 nm, or the like can be used as the laser light source 171. In this example, the laser light source 171 generates the laser light L1 at a constant repetition frequency.

The laser light L1 from the laser light source 171 is incident on the irradiation optical system 172. The irradiation optical system 172 includes an optical system that guides the laser light L1 to the workpiece W. For example, the irradiation optical system 172 may include a lens, a mirror, a filter, and the like. A laser light L2 emitted from the irradiation optical system 172 is irradiated to the workpiece W. The irradiation optical system 172 concentrates the laser light L2 onto the workpiece W. The laser light L2 passes through the dust collecting mechanism 130 and is incident on the workpiece W.

The irradiation optical system 172 includes, for example, a cylindrical lens or the like which forms a linear irradiation region 175. As shown in FIG. 2, the line direction of the irradiation region 175 is parallel to the Z direction. The Z direction is the longitudinal direction of the linear irradiation region 175, and the X direction is the lateral direction perpendicular to the longitudinal direction. The irradiation region 175 is formed so as to extend in the Z direction over almost the entire workpiece W. The laser irradiation unit 170 irradiates the workpiece W with the laser light L2 while the conveyance stage 150 is conveying the workpiece W in the X direction. Thus, almost the entire workpiece W can be irradiated with the laser light L2.

Further, the irradiation optical system 172 includes a shutter 173. The shutter 173 is disposed so as to be insertable and removable in an optical path of the laser light L1. That is, the shutter 173 is removed from the optical path while the workpiece W is irradiated with the laser light L2. Further, the shutter 173 is inserted into the optical path while the workpiece W is not irradiated with the laser light L2.

As shown in FIG. 3, the observation apparatus 110 includes an illumination light source 111, a photodetector 112, a beam splitter 113, and the like. The illumination light source 111 includes a Light Emitting Diode (LED) light source and the like, and generates an illumination light L3 for illuminating the workpiece W. The illumination light L3 is reflected on the beam splitter 113 and incident on the workpiece W. The beam splitter 113 is a half mirror or the like. A part of the light scattered or reflected by the workpiece W becomes a detection light L4. The detection light L4 passes through the beam splitter 113 and is incident on the photodetector 112.

The photodetector 112 detects the detection light L4 from an illumination region of the workpiece W. Specifically, the illumination light illuminates a linear illumination region along the Z direction in the workpiece W. For example, the illumination light source 111 may include a plurality of LED light sources arranged side by side in the X direction. The photodetector 112 is a line sensor in which a plurality of pixels are arranged side by side in the Z direction. That is, the photodetector 112 is a line camera that captures a one-dimensional image. The photodetector 112 detects the detection light L4 from the workpiece W while the conveyance stage 150 is conveying the workpiece W. Since the workpiece W passes through the field of view of the photodetector 112 in the X direction, the observation apparatus 110 can capture a two-dimensional image of the workpiece W.

The illumination light L3 from the illumination light source 111 illuminates almost the entire workpiece W in the Z direction. The photodetector 112 detects the detection light L4 from almost the entire workpiece W in the Z direction. The conveyance stage 150 conveys the workpiece W in the X direction so that the workpiece W passes through the illumination region. Thus, an image of almost the entire workpiece W is captured. The observation apparatus 110 outputs the captured image of the entire surface of the workpiece W to the processing unit 20 (see FIG. 1). Each pixel data of the captured image indicates the luminance of the detection light L4. Further, the address of each pixel indicates the position in the workpiece W.

When a foreign matter or the like adheres to the surface of the workpiece W, the amount of the detection light L4 changes. Therefore, the observation apparatus 110 detects the detection light L4 reflected on the surface of the workpiece W and captures an image of the workpiece W. Note that optical elements such as a lens and a filter (not shown) may be disposed in the observation apparatus 110.

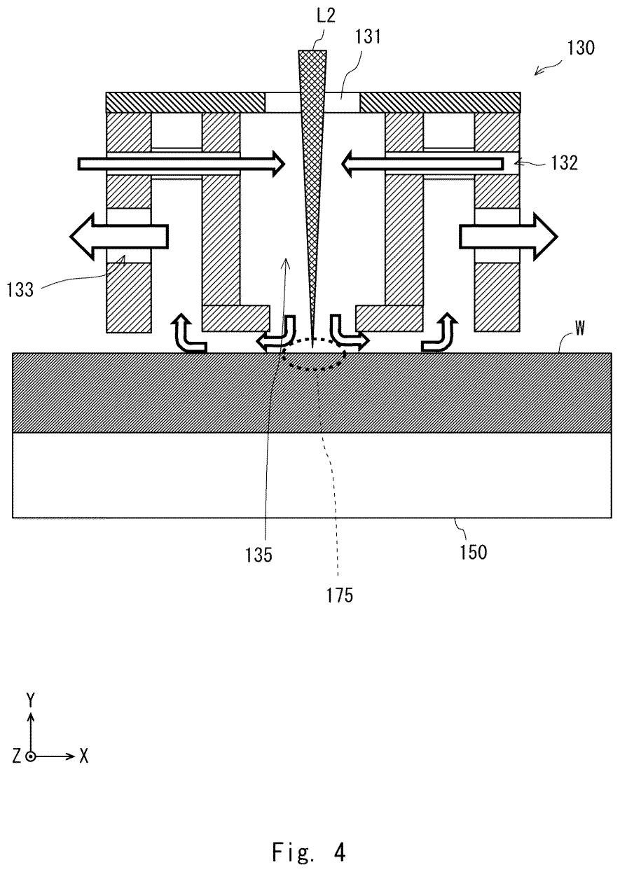

The dust collecting mechanism 130 is disposed directly above the irradiation region 175 of the laser light L1. That is, the dust collecting mechanism 130 is disposed directly under the irradiation optical system 172 of the laser irradiation unit 170. The dust collecting mechanism 130 exhausts gas directly above the irradiation region 175. An example of a configuration of the dust collecting mechanism 130 will be described with reference to FIG. 4. FIG. 4 is a sectional side view showing the configuration of the dust collecting mechanism 130. The dust collecting mechanism 130 can be formed of a metallic material such as stainless steel or a resin material.

The dust collecting mechanism 130 includes a window part 131, an ejection part 132, and an exhaust part 133. The window part 131 is disposed directly above the irradiation region 175. The laser light L2 passes through the window part 131 and is incident on the workpiece W. The window part 131 is formed of a transparent material such as a glass substrate.

The ejection part 132 is connected to a gas supply pipe for supplying gas, and ejects gas to the upper surface of the workpiece W. Specifically, the ejection part 132 ejects gas to a space 135 directly under the window part 131. Dusts (particles) present on the surface of the workpiece W can be blown away by the gas from the ejection part 132.

The exhaust part 133 exhausts gas present directly above the workpiece W. For example, the exhaust part 133 is connected to an exhaust pipe for exhausting gas. The exhaust part 133 exhausts gas present in the space 135 directly below the window part 131. The dust collecting mechanism 130 sucks gas present in the irradiation region 175 of the laser light L2. Thus, dusts can be sucked from the exhaust part 133. Therefore, since a foreign matter over the workpiece W can be removed, the workpiece W can be appropriately irradiated with the laser light L2. As a result, the productivity of a laser lift-off process can be improved.

Referring back to FIGS. 2 and 3, the explanation will be continued. Note that an end part of the LLO apparatus 100 on the −X side thereof is a position to which the workpiece W is carried in and a position from which the workpiece W is carried out. The conveyance stage 150 conveys the workpiece W in the X direction in a reciprocating manner. The observation apparatus 110 captures an image of the workpiece W both before it is irradiated with a laser light and after it is irradiated with a laser light. That is, the workpiece W is inspected both before it is irradiated with a laser light and after it is irradiated with a laser light.

For example, in a state in which the conveyance stage 150 is at the end part of the LLO apparatus 100 on the −X side thereof, a conveyance robot carries the workpiece W above the conveyance stage 150. Further, the conveyance stage 150 conveys the workpiece W in the +X direction, whereby the workpiece W passes through the observation apparatus 110. Thus, an image of the workpiece W before it is irradiated with a laser light is captured. The conveyance stage 150 further moves the workpiece W that has passed through the observation apparatus 110 in the +X direction, whereby the workpiece W passes through the laser irradiation unit 170. Thus, the workpiece W is irradiated with the laser light L1.

When the irradiation of the laser light L1 is completed, the conveyance stage 150 moves the workpiece W in the −X direction. Thus, the workpiece W passes through the laser irradiation unit 170 and the observation apparatus 110 in this order. When the workpiece W passes through the observation apparatus 110 in the −X direction, an image of the workpiece W that has been irradiated with the laser light is captured. The conveyance stage 150 further conveys the workpiece W in the −X direction and moves it to the position from which the workpiece W is carried out. Then, the conveyance robot carries out the processed workpiece W from the LLO apparatus 100. In this way, the conveyance stage 150 moves the workpiece W in a reciprocating manner so that the workpiece W passes through the observation apparatus 110, the laser irradiation unit 170, and the observation apparatus 110 in this order.

Referring back to FIG. 1, the explanation will be continued. The observation apparatus 110 outputs image data of the captured image of the workpiece W to the processing unit 20. The processing unit 20 is an information processing apparatus of a personal computer and includes a memory, a processor, and the like. The processing unit 20 stores a program for inspecting the workpiece W using the image data of the captured image.

The processing unit 20 determines whether or not a foreign matter adheres to the workpiece W. The processing unit 20 determines whether or not the workpiece W is defective based on a result of the detection of a foreign matter. When, for example, a foreign matter having a size larger than a threshold is detected, the processing unit 20 determines that the workpiece W is defective. When a foreign matter having a size larger than a threshold is not detected, the processing unit 20 determines that the workpiece W is non-defective.

The processing unit 20 outputs a result of the determination as to whether or not the workpiece W is defective to the display 10 and the control unit 30. The display 10 displays the result of the determination as to whether or not the workpiece W is defective. For example, when it is determined that the workpiece W is defective, the display 10 generates an alarm. Further, the display 10 may display an image of a part of the workpiece W to which a foreign matter adheres.

The control unit 30 is a controller such as a Programmable Logic Controller (PLC) and controls the conveyance stage 150. The control unit 30 controls the conveyance stage 150 so that the workpiece W is conveyed at a

Further, the control unit 30 controls the conveyance stage 150 based on the result of the determination. When it is determined that the workpiece W is defective, the control unit 30 controls the conveyance stage 150 so that the workpiece W is not conveyed toward the laser irradiation unit 170.

When it is determined that the workpiece W is non-defective, the control unit 30 controls the conveyance stage 150 so that the workpiece W is conveyed toward the laser irradiation unit 170. Further, the control unit 30 controls the conveyance stage 150 so that the workpiece W is conveyed toward the observation apparatus 110 in order for the observation apparatus 110 to capture an image of the workpiece W that has been irradiated with the laser light.

For example, when it is determined that the workpiece W is defective in the inspection before the workpiece W is irradiated with the laser light, the control unit 30 controls the conveyance stage 150 so that the workpiece W is not conveyed toward the laser irradiation unit 170. The conveyance stage 150 moves the workpiece W in the −X direction at the time when it is detected that the workpiece W is a defective workpiece. That is, the conveyance stage 150 reverses the conveying direction, and hence the workpiece W is moved to the position from which the workpiece W is carried out. Therefore, the workpiece W which is determined to be defective is carried out from the LLO apparatus 100 without being irradiated with the laser light.

When a foreign matter is present over the workpiece W, a laser light is absorbed by the foreign matter. Therefore, the separating layer cannot be irradiated with a sufficient amount of laser light, and hence a failure of separation in a position where the foreign matter is present may occur. Thus, in the workpiece W to which a large foreign matter adheres, there is a high possibility that a failure of separation will occur. In this embodiment, the workpiece W is carried out from the LLO apparatus 100 without being irradiated with a laser light. Thus, the productivity can be improved.

When it is determined that the workpiece W is non-defective in the inspection before the workpiece W is irradiated with a laser light, the conveyance stage 150 conveys the workpiece W toward the laser irradiation unit 170. The workpiece W passes through the laser irradiation unit 170, whereby the workpiece W is irradiated with the laser light. The conveyance stage 150 conveys the workpiece W that has been irradiated with the laser light toward the observation apparatus 110. The workpiece W passes through the observation apparatus 110, whereby an image of the workpiece W that has been irradiated with the laser light is captured. Then the processing unit 20 determines whether or not the workpiece W is defective based on the captured image of the workpiece W that has been irradiated with the laser light.

The workpiece W which is determined to be defective before it is irradiated with the laser light may be subjected to a cleaning process. By doing so, a foreign matter can be removed. Then, after the cleaning process, the workpiece W may be carried into the LLO apparatus 100 again. Therefore, the productivity can be further improved. The workpiece W which is determined to be defective before or after it is irradiated with the laser light may be set as a rejected lot.

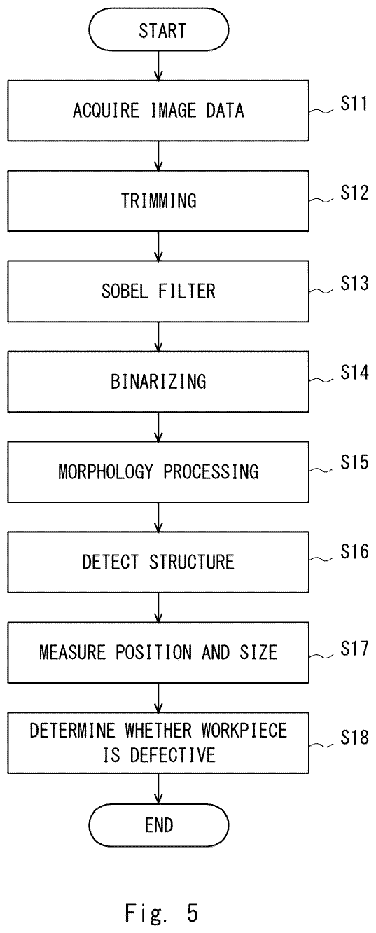

An example of processing for determining whether or not a workpiece is defective performed by the processing unit 20 will be described with reference to FIG. 5. FIG. 5 is a flowchart showing the processing performed by the processing unit 20. The processing unit 20 performs image processing in accordance with the flow shown in FIG. 5, thereby determining whether or not a workpiece is defective. In the processing described below, one or more steps may be omitted.

First, the processing unit 20 acquires image data captured by the observation apparatus 110 (S11). The processing unit 20 trims the image data (S12). For example, the processing unit 20 removes a stage or the like by the trimming. The processing unit 20 performs processing using a Sobel filter (a gradient filter) on the trimmed image data (S13). As a result, a part of the image data where the amount of change in the luminance is large is extracted.

The processing unit 20 binarizes the image data on which filter processing has been performed (S14). For example, the processing unit 20 compares luminance data of each pixel with a predetermined threshold, thereby converting the image data into a binarized image (a black and white image). The processing unit 20 performs morphology processing on the binarized image (S15). The processing unit 20 performs expansion and contraction, whereby gaps in the binarized image can be filled. Specifically, the processing unit 20 performs expansion processing for expanding white pixels of the binarized image by one pixel, and contraction processing for narrowing white pixels of the image data on which the expansion processing has been performed by one pixel. By doing so, noise components can be removed.

The processing unit 20 detects a structure from the image data (S16). For example, the processing unit 20 detects a pixel larger than a specific pixel as a structure. The processing unit 20 measures a position and a size of the structure (S17). The processing unit 20 determines whether or not the workpiece is defective based on the position and the size of the structure (S18). For example, when the size of a foreign matter is 20 μm or greater, the processing unit 20 determines that the workpiece is defective. Further, when the foreign matter is located at a position that does not affect the separation process, the processing unit 20 may determine that the workpiece is non-defective. As a matter of course, the criterion for determining whether or not the workpiece is defective can be appropriately changed in accordance with operation conditions, laser irradiation conditions, and the like.

By doing the above, it is possible to appropriately determine whether or not a workpiece is defective. Therefore, it is possible to accurately determine whether a workpiece is defective or non-defective, and the productivity of the LLO process can be improved.

Each of the processing unit 20 and the control unit 30 is not limited to a single physical apparatus, and may be disposed in a plurality of apparatuses in a distributed manner. That is, the processing unit 20 and the control unit 30 may include a plurality of memories and a plurality of processors.

Further, some or all of the above-described processes performed by the processing unit 20, the control unit 30, and the like can be implemented as a computer program. The above program can be stored and provided to a computer using any type of non-transitory computer readable media. Non-transitory computer readable media include any type of tangible storage media. Examples of non-transitory computer readable media include magnetic storage media (such as flexible disks, magnetic tapes, hard disk drives, etc.), optical magnetic storage media (e.g., magneto-optical disks), CD-ROM (Read Only Memory), CD-R, CD-R/W, and semiconductor memories (such as mask ROM, PROM (Programmable ROM), EPROM (Erasable PROM), flash ROM, RAM (Random Access Memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g., electric wires and optical fibers) or a wireless communication line.

A laser irradiation method according to this embodiment includes the following steps (a) to (h).
(a) capturing an image of a workpiece by causing a conveyance stage to convey the workpiece so that the workpiece including a separating layer to be separated by laser lift off passes through an observation apparatus
(b) determining whether or not the workpiece is defective based on the captured image of the workpiece
(c) controlling, when it is determined that the workpiece is defective, the conveyance stage so that the workpiece is not conveyed toward a laser irradiation unit
(d) controlling, when it is determined that the workpiece is non-defective, the conveyance stage so that the workpiece is conveyed toward the laser irradiation unit
(e) causing the laser irradiation unit to irradiate the workpiece with a laser light along a line direction inclined from a conveying direction in a top view
(f) sucking gas in a vicinity of an irradiation region of the laser light
(g) capturing an image of the workpiece by causing the conveyance stage to convey the workpiece so that the workpiece that has been irradiated with the laser light passes through the observation apparatus
(h) determining whether or not the workpiece is defective based on the captured image of the workpiece that has been irradiated with the laser light

Thus, irradiation of a laser light for a laser lift-off process can be achieved with a high productivity.

### Organic EL Display

The laser irradiation system 1 is suitably used for a laser lift-off apparatus for an organic ElectroLuminescence (EL) display. That is, a laser irradiation method performed by the laser irradiation system 1 is used as a laser lift-off process in a manufacturing process of the organic EL display.

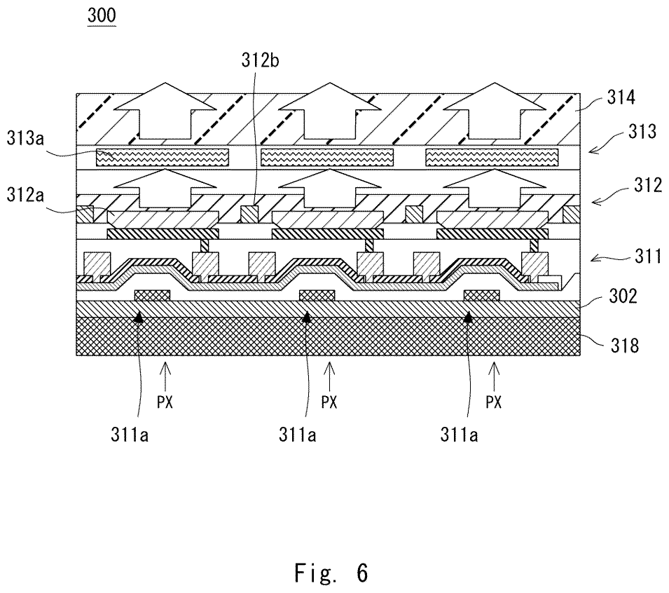

A configuration applied to the organic EL display manufactured using the laser irradiation system 1 according to this embodiment will be described below. A structure of an organic Electroluminescence (EL) display will be described with reference to FIG. 6. FIG. 6 is a cross-sectional view illustrating an example of an organic EL display. An organic EL display 300 illustrated in FIG. 6 is an active-matrix display apparatus which includes a TFT disposed in each pixel PX.

The organic EL display 300 includes a film 318, a separating layer 302, a Thin Film Transistor (TFT) layer 311, an organic layer 312, a color filter layer 313, and a protection layer 314. FIG. 6 illustrates a top-emission organic EL display in which the side on which the protection layer 314 is located becomes a viewing side. Note that the following description is given by using one configuration example of the organic EL display, and the present embodiment is not limited to the configuration described below. For example, in the present embodiment, a bottom-emission organic EL display may be used.

The film 318 is a flexible plastic film, and is a film which can be bent by applying a stress thereto. The separating layer 302 and the TFT layer 311 are provided over the film 318. The TFT layer 311 includes TFTs 311a disposed in respective pixels PX. Furthermore, the TFT layer 311 includes a wire (not illustrated) connected to the TFT 311a. The TFT 311a and the wire constitute a pixel circuit.

The organic layer 312 is provided over the TFT layer 311. The organic layer 312 includes organic EL light emitting elements 312a disposed for respective pixels PX. The organic EL light emitting element 312a has, for example, a laminated structure in which an anode, a hole injection layer, a hole transport layer, a light emitting layer, an electron transport layer, an electron injection layer and a cathode are laminated. In the case of the top-emission type, the anode is a metal electrode, and the cathode is a transparent conductive film such as an Indium Tin Oxide (ITO). Furthermore, the organic layer 312 is provided with a partitioning wall 312b which separates organic EL light emitting elements 312a of adjacent pixels PX.

The color filter layer 313 is provided over the organic layer 312. The color filter layer 313 is provided with color filters 313a for displaying color images. That is, each pixel PX is provided with one of the color filters 313a each of which is a resin layer colored R (red), G (green) or B (blue). When white light emitted from the organic layer 312 passes the color filter 313a, it is converted into light having one of RGB colors. In addition, in the case of a three-color system in which the organic layer 312 is provided with organic EL light emitting elements each of which emits light having a respective one of the RGB colors, the color filter layer 313 may be omitted.

The protection layer 314 is provided over the color filter layer 313. The protection layer 314 is made of a resin material, and is provided to prevent deterioration of the organic EL light emitting elements of the organic layer 312.

A current flowing in the organic EL light emitting elements 312a of the organic layer 312 changes according to a display signal supplied to the pixel circuit. Consequently, by supplying a display signal corresponding to a display image to each pixel PX, it is possible to control a light emission amount of each pixel PX. Consequently, it is possible to display a desired image.

### Manufacturing Process of Organic EL Display

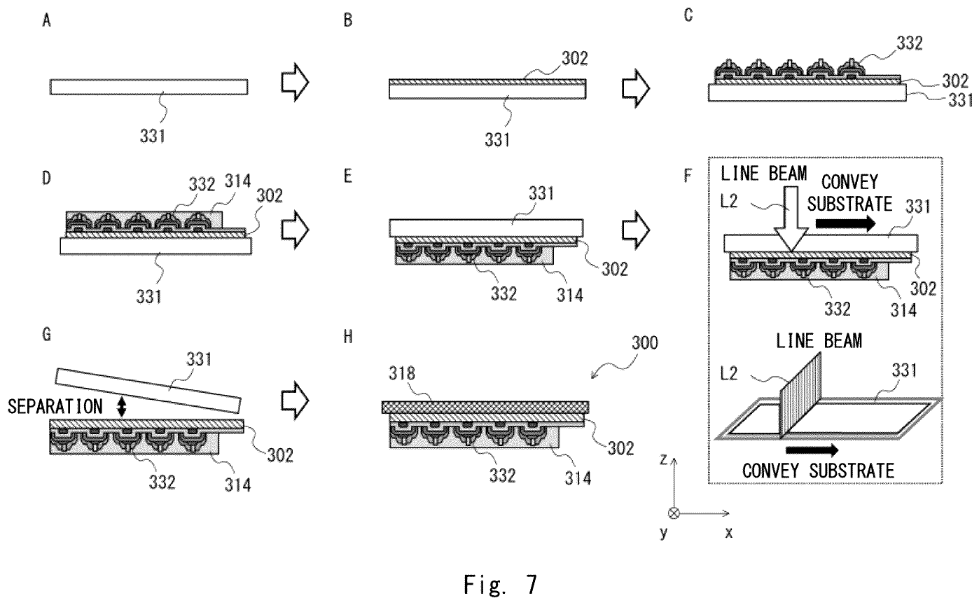

Next, the manufacturing process of the organic EL display described above with reference to FIG. 7 will be described. When the organic EL display is manufactured, a processing substrate 331 is prepared first (process A). For example, a glass substrate which allows transmission of laser light is used for the processing substrate 331. The processing substrate 331 corresponds to each of the workpieces W shown in FIGS. 2 to 4.

Next, the separating layer 302 is formed over the processing substrate 331 (process B). For example, a polyimide can be used for the separating layer 302. Subsequently, a circuit element 332 is formed over the separating layer 302 (process C). In this regard, the circuit element 332 includes the TFT layer 311, the organic layer 312 and the color filter layer 313 illustrated in FIG. 6. The circuit element 332 can be formed by using a photolithography technique or a film formation technique. Subsequently, the protection layer 314 which protects the circuit element 332 is formed over the circuit element 332 (process D).

Next, the processing substrate 331 is reversed such that the processing substrate 331 faces upward (process E). After the reversed processing substrate 331 is cleaned by a cleaning machine, it is carried into the LLO apparatus 100.

The separating layer 302 is irradiated with the laser light L2 from a side of the processing substrate 331 (process F). A line beam can be used for the laser light L2. In a case of FIG. 7, the processing substrate 331 is conveyed in the X direction, so that the laser light L2 is irradiated from a right side to a left side of the processing substrate 331. Note that, before and after the process F, the observation apparatus 110 captures images of the workpiece W as described above. Then the processing unit 20 determines whether or not the workpiece W is defective based on the captured images of the workpiece W. Therefore, only the non-defective workpiece proceeds to the next process. Further, when it is determined that the workpiece W is defective, the workpiece W may be carried into a cleaning apparatus and then cleaned.

Subsequently, the processing substrate 331 and the separating layer 302 are separated (process G). Lastly, the film 318 is laminated over the separating layer 302 (process H). For example, the film 318 is a flexible plastic film, and is a film which can be bent by applying a stress thereto. By using this manufacturing process, it is possible to manufacture the bendable organic EL display 300.

Note that the present invention is not limited to the above-described embodiments and may be changed as appropriate without departing from the scope and spirit of the present invention.

This application is based upon and claims the benefit of priority from Japanese patent application No. 2022-168424, filed on Oct. 20, 2022, the disclosure of which is incorporated herein in its entirety by reference.

### REFERENCE SIGNS LIST

1 LASER IRRADIATION SYSTEM
10 DISPLAY
20 PROCESSING UNIT
30 CONTROL UNIT
100 LLO APPARATUS
110 OBSERVATION APPARATUS
111 ILLUMINATION LIGHT SOURCE
112 PHOTODETECTOR
113 BEAM SPLITTER
130 DUST COLLECTING MECHANISM
131 WINDOW PART
132 EJECTION PART
133 EXHAUST PART
135 SPACE
150 CONVEYANCE STAGE
170 LASER IRRADIATION UNIT
171 LASER LIGHT SOURCE
172 IRRADIATION OPTICAL SYSTEM
175 IRRADIATION REGION
W WORKPIECE
300 ORGANIC EL DISPLAY
311 TFT LAYER
311a TFT
312 ORGANIC LAYER
312a ORGANIC EL LIGHT EMITTING ELEMENT
312b PARTITIONING WALL
313 COLOR FILTER LAYER
313a COLOR FILTER (CF)
314 PROTECTION LAYER
PX PIXEL

1. A laser irradiation system comprising:
a conveyance stage configured to convey a workpiece including a separating layer to be separated by laser lift off;
an observation apparatus configured to capture an image of the workpiece by detecting light from the workpiece being conveyed;
a laser irradiation unit configured to irradiate the workpiece, which is inspected by the observation apparatus, with a laser light along a line direction inclined from a conveying direction in a top view;
a dust collecting mechanism configured to suck gas in a periphery of an irradiation region of the laser light;
a processing unit configured to determine whether or not the workpiece is defective based on a captured image of the workpiece captured before the workpiece is irradiated with the laser light; and
a control unit configured to control, when it is determined that the workpiece is defective, the conveyance stage so that the workpiece is not conveyed toward the laser irradiation unit, and control, when it is determined that the workpiece is non-defective, the conveyance stage so that the workpiece that has been irradiated with the laser light is conveyed toward the observation apparatus in order for the observation apparatus to inspect the workpiece.

2. The laser irradiation system according to claim 1, wherein
the dust collecting mechanism comprises:
a window part through which the laser light passes;
an ejection part configured to eject gas to the workpiece; and
an exhaust part configured to suck gas present in the irradiation region of the laser light.

3. The laser irradiation system according to claim 1, wherein
the processing unit performs filter processing using a gradient filter on image data of the captured image of the workpiece,
the processing unit binarizes the image data on which the filter processing has been performed,
the processing unit performs morphology processing on the binarized image data,
the processing unit detects a structure from the image data on which the morphology processing has been performed, and
the processing unit determines whether or not the workpiece is defective based on a size of the structure.

4. A laser irradiation method comprising the steps of:
(a) capturing an image of a workpiece by causing a conveyance stage to convey the workpiece so that the workpiece including a separating layer to be separated by laser lift off passes through an observation apparatus;
(b) determining whether or not the workpiece is defective based on the captured image of the workpiece;
(c) controlling, when it is determined that the workpiece is defective, the conveyance stage so that the workpiece is not conveyed toward a laser irradiation unit;
(d) controlling, when it is determined that the workpiece is non-defective, the conveyance stage so that the workpiece is conveyed toward the laser irradiation unit;
(e) causing the laser irradiation unit to irradiate the workpiece with a laser light along a line direction inclined from a conveying direction in a top view;
(f) sucking gas in a vicinity of an irradiation region of the laser light;
(g) capturing an image of the workpiece by causing the conveyance stage to convey the workpiece so that the workpiece that has been irradiated with the laser light passes through the observation apparatus; and
(h) determining whether or not the workpiece is defective based on the captured image of the workpiece that has been irradiated with the laser light.

5. The laser irradiation method according to claim 4, wherein
in the step (f), a dust collecting mechanism sucks the gas present in the irradiation region of the laser light, and
the dust collecting mechanism comprises:
a window part through which the laser light passes; and
an ejection part configured to eject gas to the workpiece.

6. The laser irradiation method according to claim 4, wherein
in the step of determining whether or not the workpiece is defective,
filter processing using a gradient filter is performed on image data of the captured image of the workpiece,
the image data on which the filter processing has been performed is binarized,
morphology processing is performed on the binarized image data,
a structure is detected from the image data on which the morphology processing has been performed, and
whether or not the workpiece is defective is determined based on a size of the structure.

7. A method for manufacturing an organic EL display comprising the processes of:
(SA) forming a separating layer over a substrate;
(SB) forming an element over the separating layer;
(SC) separating the substrate from the separating layer; and
(SD) laminating a film over the separating layer, wherein
the process (SC) of separating the substrate from the separating layer comprises the steps of:
(C1) capturing an image of a substrate by causing a conveyance stage to convey the substrate so that the substrate passes through an observation apparatus;
(C2) determining whether or not the substrate is defective based on the captured image of the substrate;
(C3) controlling, when it is determined that the substrate is defective, the conveyance stage so that the substrate is not conveyed toward a laser irradiation unit;
(C4) controlling, when it is determined that the substrate is non-defective, the conveyance stage so that the substrate is conveyed toward the laser irradiation unit;
(C5) causing the laser irradiation unit to irradiate the substrate with a laser light along a line direction inclined from a conveying direction in a top view;
(C6) sucking gas in a vicinity of an irradiation region of the laser light;
(C7) capturing an image of the substrate by causing the conveyance stage to convey the substrate so that the substrate that has been irradiated with the laser light passes through the observation apparatus; and
(C8) determining whether or not the substrate is defective based on the captured image of the substrate that has been irradiated with the laser light.

8. The method for manufacturing an organic EL display according to claim 7, wherein
in the step (C6), a dust collecting mechanism sucks the gas present in the irradiation region of the laser light, and
the dust collecting mechanism comprises:
a window part through which the laser light passes; and
an ejection part configured to eject gas to the workpiece.

9. The method for manufacturing an organic EL display according to claim 7, wherein
in the step of determining whether or not the substrate is defective,
filter processing using a gradient filter is performed on image data of the captured image of the substrate,
the image data on which the filter processing has been performed is binarized,
morphology processing is performed on the binarized image data,
a structure is detected from the image data on which the morphology processing has been performed, and
whether or not the substrate is defective is determined based on a size of the structure.
